(19) United States
(12) Patent Application Publication
(10) Pub. No.: US 2009/0088001 A1
(43) Pub. Date: Apr. 2, 2009

(54) Substrate processing apparatus and manufacturing method of semiconductor device

(75) Inventor: Takashi Nakagawa, Imizu-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., Tokyo (JP)

(21) Appl. No.: 12/285,066

(22) Filed: Sep. 29, 2008

(30) Foreign Application Priority Data
Oct. 1, 2007 (JP) 2007-257199

(51) Int. Cl. H01L 21/31; C23C 16/00

(52) U.S. Cl. 438/778; 118/715; 257/E21.24

(57) ABSTRACT

To provide a large amount of processing gas to substrates. There are provided a processing chamber that stores stacked substrates; a gas supply part provided in the processing chamber along a stacking direction of the substrates, having a plurality of opening parts, for supplying a desired processing gas horizontally to surfaces of the substrates from the opening parts; and an exhaust port that exhausts an atmosphere in the processing chamber, having an upper wall and a lower wall opposed to each other across the opening parts, respectively provided on upper/lower sides of each of the opening parts of the gas supply part, and an interval between the upper wall and the lower wall opposed to each other across the opening parts being set to be gradually larger toward a supply direction of the processing gas.

### BACKGROUND

1. Technical Field

The present invention relates to a substrate processing apparatus that processes a substrate by supplying gas into a processing chamber storing the substrate, and a manufacturing method of a semiconductor device.

2. Background Art

Conventionally, a substrate processing step for forming a thin film on a substrate is executed as one step of the manufacturing steps of the semiconductor device such as a DRAM. The substrate processing apparatus for executing such a substrate processing step includes a processing chamber for storing stacked substrates; a gas supply part that supplies processing gas to the surfaces of the substrates from an opening part; and an exhaust port that exhausts an atmosphere in the processing chamber. Then, a plurality of substrates are loaded into the processing chamber, and a thin film is formed on each substrate by supplying the processing gas into the processing chamber from the opening part of the gas supply part while exhausting the inside of the processing chamber by the exhaust port, and by making the gas pass between substrates.

However, in the substrate processing step using the aforementioned substrate processing apparatus, there is a case that the processing gas supplied into the processing chamber from the opening port flows to the circumference of the substrate without passing between substrates. As a result, a supply amount of the processing gas to the substrate is reduced in some cases.

An object of the present invention is to provide the substrate processing apparatus capable of supplying a large amount of processing gas to the substrate and the manufacturing method of the semiconductor device.

### SUMMARY OF THE INVENTION

A first aspect of the present invention provides a substrate processing apparatus, including a processing chamber that stores stacked substrates; a gas supply part provided along a stacking direction of each substrate in the processing chamber, for supplying a desired processing gas horizontally to the surfaces of the substrates; and an exhaust port that exhausts an atmosphere in the processing chamber, with upper and lower sides of each opening part of the gas supply part having an upper wall and a lower wall provided respectively so as to face with each other across the opening part, and an upper wall and a lower wall facing with each other, and an interval between the upper wall and the lower wall facing with each other across the opening part, being set to be gradually larger toward a supply direction of the processing gas.

According to the substrate processing apparatus and the manufacturing method of the semiconductor device of the present invention, a large amount of processing gas can be supplied to the substrate.

### BRIEF DESCRIPTION OF THE DRAWINGS

FIG. 1 is a schematic block diagram of a thermal processing furnace included in a substrate processing apparatus according to an embodiment of the present invention, FIG. 1A shows a vertical sectional schematic view of the thermal processing furnace, and FIG. 1B shows a horizontal sectional schematic view of the thermal processing furnace shown in FIG. 1A.

FIG. 2 is an overall block diagram of the substrate processing apparatus according to an embodiment of the present invention.

FIG. 3 shows an analyzed area of a gas flow distribution in the thermal processing furnace, FIG. 3A shows a position of the analyzed area in the thermal processing furnace, and FIG. 3B shows a partially expanded view of the analyzed area, respectively.

FIG. 4 shows an analysis result of the gas flow distribution of a conventional thermal processing furnace, FIG. 4A shows an upper surface view of the analyzed area, and FIG. 4B shows a sectional view of FIG. 4A taken along the line A-A′.

FIG. 5 shows the analysis result of a pressure distribution of the conventional thermal processing furnace, FIG. 5A shows the upper surface view of the analyzed area, FIG. 5B show the analysis result in area B of FIG. 5A, FIG. 5C shows a vertical sectional view of the analyzed area, and FIG. 5D shows the analysis result in area D of FIG. 5C, respectively.

FIG. 6 shows a constitution of a gas supply part according to an embodiment of the present invention, FIG. 6A shows a perspective view of the gas supply part according to an embodiment of the present invention, and FIG. 5B shows a perspective view of the gas supply part according to another embodiment of the present invention provided with walls on both sides of the opening part, respectively.

FIG. 7 shows the analysis result of the gas flow distribution in the thermal processing furnace according to an embodiment of the present invention, FIG. 7A shows the upper surface view of the analyzed area when the walls are provided on upper/lower sides of the opening part, FIG. 7B shows a sectional view of FIG. 7A taken along the line A-A′, FIG. 7C shows the upper surface view of the analyzed area when the walls are provided on both sides of the opening part, and FIG. 7D shows the sectional view of FIG. 7C taken along the line A-A′, respectively.

FIG. 8 shows the analysis result of the pressure distribution in the thermal processing furnace according to an embodiment of the present invention, FIG. 8A shows the pressure distribution of the upper surface of the opening part when the walls are provided on the upper/lower sides of the opening part, FIG. 8B shows the vertical sectional view of FIG. 8A, FIG. 8C shows the pressure distribution of the upper surface of the opening part when the walls are provided on both sides of the opening part, and FIG. 8D shows the vertical sectional view of FIG. 8C, respectively.

FIG. 9 shows a sectional block diagram of the gas supply part according to another embodiment of the present invention.

### BEST MODE FOR CARRYING OUT THE INVENTION

As described above, in a conventional substrate processing apparatus, there is a case that a processing gas supplied into a processing chamber flows to the circumference of each substrate from an opening part, without passing between substrates.

Regarding a cause of a flow of the processing gas to the circumference of the substrate, strenuous study is performed by inventors of the present invention, while performing simulation experiments. As a result, it is found that interference of the processing gas occurs around the opening part of the gas supply part to allow a swirl to occur and also allow decrease of a local pressure to occur, with a result that the processing gas flows to a lower pressure area without passing between substrates. Then, it is possible to obtain a knowledge that in order to supply a large amount of processing gas to the substrate, it is effective to suppress the interference of the processing gas around the opening part, and suppress the generation of the swirl around the opening part. Based on such a knowledge obtained by the inventors of the present invention, the present invention is provided.

### (1) Structure of the Substrate Processing Apparatus

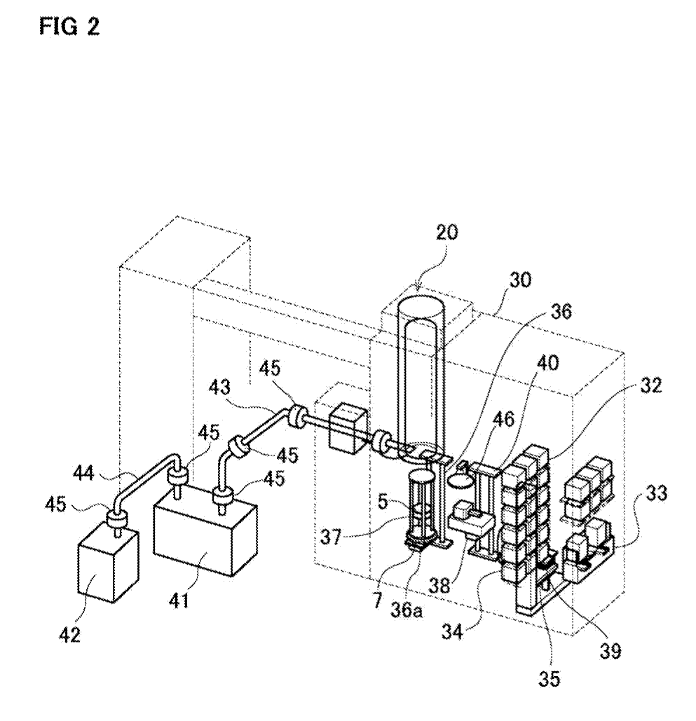

First, a structure of the substrate processing apparatus according to an embodiment of the present invention will be explained, with reference to the drawings. FIG. 2 is a schematic block diagram of the substrate processing apparatus according to an embodiment of the present invention.

As shown in FIG. 2, the substrate processing apparatus according to an embodiment of the present invention has a casing 30. An I/O stage 33 is provided on a front side in the casing 30. The I/O stage 33 is constituted so as to give and receive a cassette 32, being a substrate container, between the I/O stage 33 and an external transport device not shown. In addition, a cassette elevator 35, being an elevating unit, for elevating and moving the cassette 32 is provided behind the I/O stage 33. A cassette transfer machine 39, being a transport unit, for horizontally moving the cassette 32 is provided in the cassette elevator 35. Further, a cassette rack 34, being a placement unit of the cassette 32, is provided behind the cassette elevator 35.

A thermal processing furnace 20 for processing a substrate 5 such as a wafer is vertically provided above a rear part of the casing 30. In addition, an exhaust line 43 is connected to the thermal processing furnace 20. Detailed structures of the thermal processing furnace and the exhaust line 43 will be explained later.

A boat elevator 36, being an elevating unit, is provided below the thermal processing furnace 20. Then, an elevating member 36a is provided in a lower end portion of the boat elevator 36. A boat 37, being a substrate holding unit, is vertically fitted on the elevating member 36a, via a seal flange 7, being a lid member. The structure of the boat 37 will be described later. When the boat elevator 36 is elevated, the boat 37 is loaded to an inside of the thermal processing furnace 20, and a lower end portion of the thermal processing furnace 20 is air-tightly closed by the seal flange 7. Moreover, a furnace port shutter 46, being a closing unit, is provided on the side of the lower end portion of the thermal processing furnace 20. The furnace port shutter 46 is constituted to air-tightly close the lower end portion of the thermal processing furnace 20 during descent of the boat elevator 36.

A transfer elevator 40, being the elevating unit, for elevating and moving the substrate 5 is provided between the thermal processing furnace 20 and the cassette rack 34. A substrate transfer machine 38, being the transfer unit for horizontally moving the substrate 5, is fitted to a transfer elevator 40.

Subsequently, an operation of the aforementioned substrate processing apparatus will be explained, with reference to FIG. 2.

First, the cassette 32, on which the substrate 5 is loaded, is transported by an external transport device not shown, and placed on the I/O stage 33. Thereafter, by a cooperative movement of an elevating movement and lateral movement of the cassette elevator 35, and advancing/retreating movement and rotating movement of the cassette transfer machine 39, the cassette 32 is transferred from the I/O stage 33 to the cassette rack 34.

Thereafter, by the cooperative movement of the advancing/retreating movement and the rotating movement of the substrate transfer machine 38, and the elevating movement of the transfer elevator 40, the substrate 5 loaded to the cassette 32 on the cassette rack 34 is transferred into the boat 37 in a descent state.

Thereafter, by elevating the boat elevator 36, the boat 37 is loaded into the thermal processing furnace 20, and the inside of the thermal processing furnace 20 is air-tightly closed by the seal flange 7. Then, the substrate 5 is heated in the air-tightly closed thermal processing furnace 20, and by supplying the processing gas into the thermal processing furnace 20, prescribed processing is applied to the surface of the substrate 5. Details of such processing will be explained later.

When the processing to the substrate 5 is completed, the substrate 5 after processing is transferred into the cassette 32 on the cassette rack 34 from the boat 37. Then, the cassette 32 storing the substrate 5 after processing is transferred to the I/O stage 33 from the cassette rack 34 by the cassette transfer machine 39, and is transported to outside of the casing 30 by the external transport device. Note that after descent of the boat elevator 36, the lower end portion of the thermal processing furnace 20 is air-tightly closed by the furnace port shutter 46, thus preventing external air from entering into the thermal processing furnace 20.

### (2) Structure of the Thermal Processing Furnace

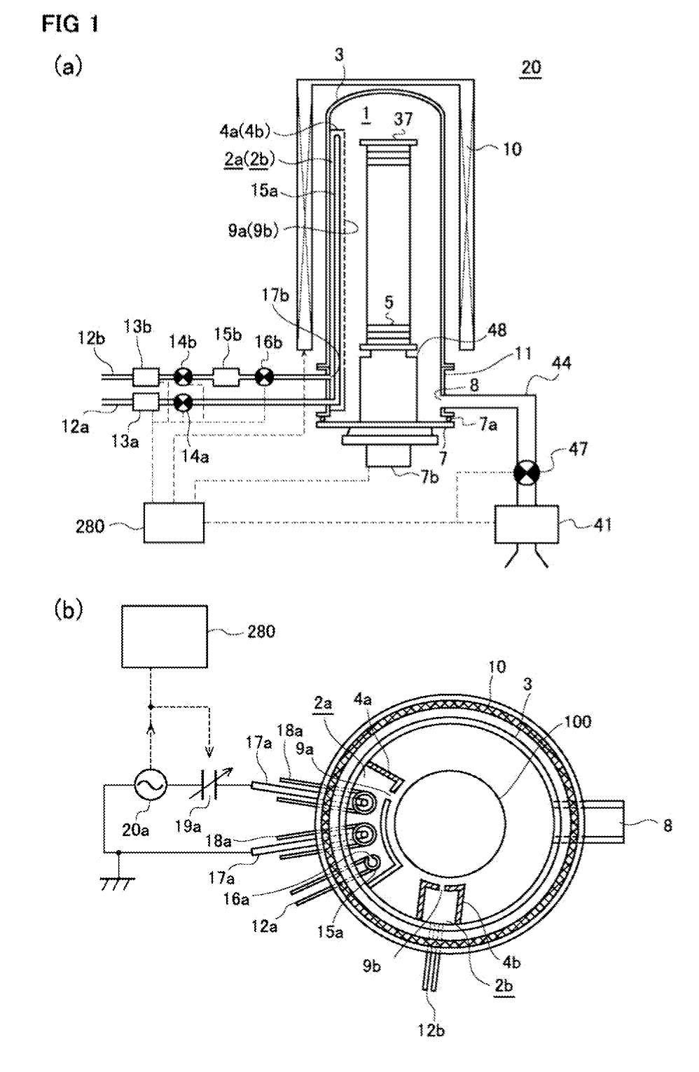

Subsequently, the structure of the thermal processing furnace according to an embodiment of the present invention will be explained, with reference to the drawings. FIG. 1 is a schematic block diagram of the thermal processing furnace included in the substrate processing apparatus according to an embodiment of the present invention, and FIG. 1A is a vertical sectional schematic view of the thermal processing furnace, and FIG. 1B is a lateral sectional schematic view of the thermal processing furnace shown in FIG. 1A, respectively.

### (Processing Chamber)

As shown in FIG. 1, the thermal processing furnace 20 according to an embodiment of the present invention has a reaction tube 3 and a manifold 11. The reaction tube 3 is constituted of a non-metal material having a heat resistance such as quartz (SiO2) and silicon carbide (Sic), and is formed in a cylindrical shape, with an upper end portion closed and lower end portion opened. In addition, the manifold 11 is constituted of a metal material such as SUS, and is formed in a cylindrical shape, with the upper end portion and the loser end portion opened. The reaction tube 3 is vertically supported from the side of the lower end portion by the manifold 11. Moreover, the reaction tube 3 and the manifold 11 are concentrically arranged. The lower end portion of the manifold 11 is air-tightly closed by the seal flange 7, when the aforementioned boat elevator 36 is elevated. A sealing member 7a such as an O-ring for air-tightly closing the inside of the processing chamber 1 is provided between the lower end portion of the manifold 11 and the seal flange 7.

The processing chamber 1 for processing the substrate 5 such as a wafer is formed in the reaction tube 3 and the manifold 11. Then, as described above, the boat 37, being a substrate holding tool, is inserted into the processing chamber 1 from below. Accordingly, inner diameters of the reaction tube 3 and the manifold 11 are set to be larger than a maximum outer shape of the boat 37 in which the substrate 5 is loaded.

The boat 37 is constituted so as to hold a plurality of substrates 5 in multiple stages at a prescribed gap (substrate pitch interval) in approximately a horizontal state. The boat 37 is mounted on a heat insulating cap 48 for blocking heat conduction from the boat 37. The heat insulating cap 48 is supported by a rotary shaft 7b from below. The rotary shaft 7b is provided so as to penetrate a center portion of the seal flange 7, while holding air-tightness in the processing chamber 1. A rotation mechanism not shown for rotating the rotary shaft 7b is provided below the seal flange 7. Accordingly, by rotating the rotary shaft 7b by the rotation mechanism, it is possible to rotate the boat 37 in which a plurality of substrates 5 are mounted, while air-tightness in the processing chamber maintained.

### (First Gas Supply Line and First Gas Supply Part)

In addition, as shown in FIG. 1, a first gas supply line 12a for supplying a first processing gas is connected to a side face of the manifold 11. A first processing gas supply source, a mass flow controller 13a, and an open/close valve 14a are provided from the upper stream side in the first gas supply line 12a. Note that an end portion of the lower stream side of the gas supply line 12a is connected to a gas supply nozzle 15a. The gas supply nozzle 15a penetrates the side face of the manifold 11, and is bent at aright angle in the processing chamber 1, and is arranged in a vertical direction along inner walls of the manifold 11 and the reaction tube 3.

A first gas supply part 4a is provided in the processing chamber 1 along the stacking direction of the substrates 5. Specifically, the first gas supply part 4a is provided so as to surround a part of a space sandwiched between the inner wall (the wall of the manifold 11 and the inner wall of the reaction tube 3) and a peripheral edge of the substrate 5 supported by the boat 37, and so as to surround an outer periphery of the gas supply nozzle 15a, and is extended in the stacking direction of the substrates 5 (vertical direction) from a lower side in the processing chamber 1. Then, a buffer space 2a is formed in a space surrounded by the inner wall of the first gas supply part 4a and the inner wall of the processing chamber 1, for alleviating a difference in a speed of a gas molecule by temporarily storing the processing gas supplied from the first gas supply line 12a.

In a buffer space 2a, a pair of electrodes 17a are extended toward the stacking direction (vertical direction) of the substrates 5 along the inner walls of the manifold 11 and the reaction tube 3. An external power source 20a is connected to the pair of electrodes 27 via an impedance matching apparatus 19a. The pair of electrodes 17a are covered with a cylindrical protective tube 18a made of dielectric material, respectively. The upper end portion of the protective tube 18a is closed and the lower end portion of the protective tube 18a is opened, to communicate with outside of the processing chamber 1, and inert gas is purged in the protective tube 18a. In addition, although not shown, a held part in the vicinity of the bending part of the electrode 17a is covered with an insulating cylinder for preventing discharge and a shield cylinder for electrostatic block. By applying a high frequency power to the pair of electrodes 17a using the external power source 20a, plasma (namely, plasma discharge area) is generated (ignited) in the buffer space 2a. The plasma generated (ignited) by the electrode 17a activates the first processing gas supplied into the buffer space 2a.

In addition, the first gas supply part 4a has a plurality of opening parts 9a. Specifically, a plurality of opening parts 9a are provided on the side wall of the first gas supply part 4a opposed to the peripheral edge of each substrate 5 along the stacking direction of the substrates 5. Each opening part 9a is opened toward a center of the processing chamber 1 (center of the substrate 5). As a result, the first processing gas supplied into the buffer space 2a and activated by plasma is supplied (ejected) upward of each substrate 5 stored in the processing chamber 1. Note that when the pressure in the buffer space 2a is different, for example, a diameter of the opening part 9a on the upper stream side of a gas flow (lower side of the processing chamber 1) is set to be small, and by setting the diameter of the opening part 9a on the lower stream side of the gas flow (upper side of the processing chamber 1) large, a supply amount of the processing gas to each substrate 5 can be made uniform, irrespective of a placement position (height) of the substrate 5.

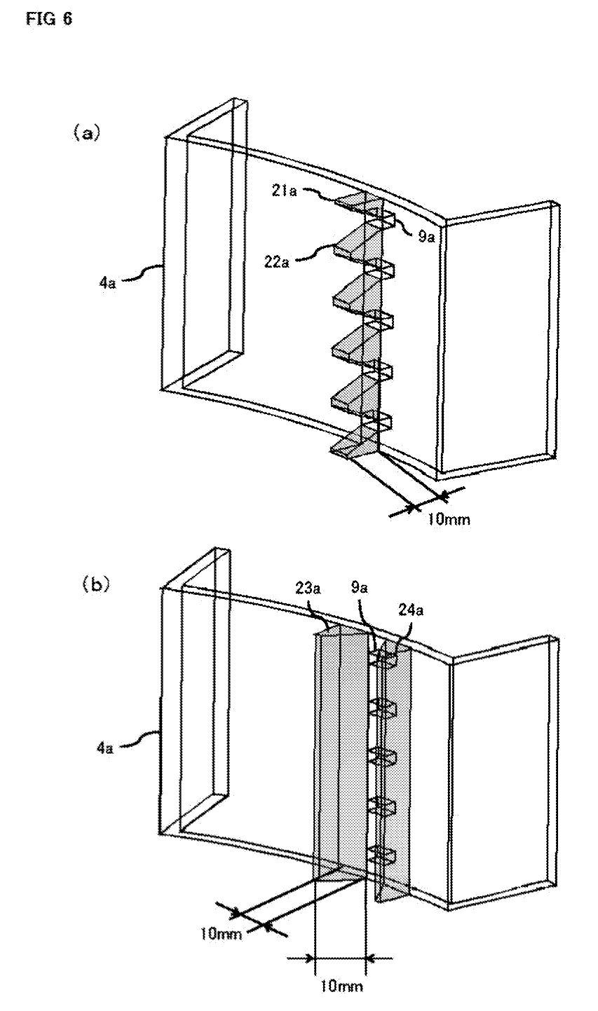

Note that as shown in FIG. 6A, an upper wall 21a and a lower wall 22a opposed to each other across each opening part 9a, are provided on upper and lower sides of each opening part 9a of the first gas supply part 4a. Then, the interval between the upper wall 21a and the lower wall 22a opposed to each other across the opening part 9a, is set to be gradually larger toward the supply direction (namely the direction toward the center of the substrate from the opening parts 9a) of the processing gas. As a result, it is possible to suppress the generation of the swirl around the opening part 9a and a local decrease of pressure, thus making it possible to suppress the flow of the first processing gas to the circumference of the substrate 5 without passing between substrates 5. Here, by making a lower stream side end portion of the upper wall 21a and a lower stream side end portion of the lower wall 22a approach the peripheral edge portion of the substrate 5 respectively, the speed of the processing gas on the substrate 5 can be increased.

### (Second Gas Supply Line and Second Gas Supply Part)

Also, as shown in FIG. 1, a second gas supply line 12b for supplying a second processing gas is connected to the side face of the manifold 11. A second processing gas supply source not shown, a mass flow controller 13b, an open/close valve 14b, a gas reservoir 15b constituted as a buffer tank, and an open/close valve 16b are provided in the second gas supply line 12b from the upper stream side. Note that a second gas inlet port 17b are formed on the side face of the manifold 11 on the lower stream side of the second gas supply line 12b.

In the processing chamber 1, a second gas supply part 4b is provided along the stacking direction of the substrates 5. Specifically, the second gas supply part 4b is provided so as to surround a part of the space sandwiched between the inner wall of the processing chamber 1 and the peripheral edge of the substrate 5 supported by the boat 37, and is extended toward the stacking direction (vertical direction) of the substrates 5 from the lower side (lower side of the second gas inlet port 17b) in the processing chamber 1. Then, a buffer space 2b for alleviating the difference in the speed of the gas molecule by temporarily storing the processing gas supplied from the second gas supply line 12b is formed in a space surrounded by the inner wall of the second gas supply part 4b and the inner wall of the processing chamber 1.

The second gas supply part 4b also has a plurality of opening parts 9b similarly to the first gas supply part 4a. Also, similarly to the first gas supply part 4a, an upper wall 21b and a lower wall 22b opposed to each other across each opening part 9b, are respectively provided on the upper and lower sides of each opening part 9b of the second gas supply part 4b.

### (Exhaust Port)

As shown in FIG. 1, an exhaust port 8 for exhausting the atmosphere in the processing chamber 1 is provided on the side wall of the manifold 11. In addition, an exhaust line 43 shown in FIG. 2 is connected to the exhaust port 8. The lower stream side end portion of the exhaust line 43 is connected to a vacuum pump 41. An open/close valve 47 is provided in the exhaust line 43. By adjusting an opening degree of the open/close valve 47 while operating the vacuum pump 41, the pressure in the processing chamber 1 can be adjusted. A discharge port of the vacuum pump 41 is connected to a discharge gas excluding device 42 by a piping 44. Note that when the exhaust line 43 and the piping 44 are constituted of a plurality of piping, a joint part 45 is provided as needed.

### (Resistance Heating Heater)

As shown in FIG. 1, a resistance heating heater 10, being a heating unit, is provided so as to surround an outer periphery of the reaction tube 3. By supplying power to the resistance heating heater 10, the inside of the processing chamber 1 is heated form outside of the reaction tube 3. Thus, by constituting the resistance heating heater 10 as a hot wall type structure, a temperature can be maintained uniformly over an entire body of the inside of the processing chamber 1.

### (Controller)

A controller 280 is provided in the thermal processing furnace 20. The controller 280 is connected to open/close valves 14a, 14b, 16b, 47, mass flow controllers 13a, 13b, a rotating unit for rotating the rotary shaft 7b, the impedance matching apparatus 19a, the external power source 20a, the vacuum pump 41, and the resistance heating heater 10, respectively, so as to control operations of them.

### (4) Substrate Processing Step

Subsequently, a substrate processing step as an embodiment of the present invention will be explained, with reference to the drawings. Note that this embodiment shows a method of forming a SiN (nitride silicon) film on a surface of the substrate 5 by using an ALD (Atomic Layer Deposition) method, being one of CVD (Chemical Vapor Deposition) methods, and is executed as one step of the manufacturing step of the semiconductor device. Note that in an explanation given hereunder, the operation of each part constituting the substrate processing apparatus is controlled by the controller 280.

The ALD method is a technique of alternatively supplying to the substrate 5 the processing gas, being two kinds (or more kinds) of raw materials used in film deposition, which is then adsorbed on the surface of the substrate 5 per unit of one atomic layer, to deposit the film using a surface reaction. For example, when the SiN film is formed, NH₃ (ammonia) is used as the first processing gas, and a DCS gas (SiH₂Cl₂, dichlorosilane) gas is used as the second processing gas. By repeating a cycle of supplying these processing gases alternatively to the substrate 5 by each one kind, control of a film thickness is performed. For example, when a film deposition speed is set at 1 Å, 20 cycles of processing is performed.

### (Substrate Loading Step (S1))

First, the substrate 5, being a processing object, is charge into the boat 37. Subsequently, the boat elevator 36 is elevated, to load the boat 37 having the substrate 5 charged therein into the processing chamber 1, and the inside of the processing chamber 1 is air-tightly closed by the seal flange 7. At this time, open/close valves 14a, 14b, 16b, and 47 are closed. After loading the substrate 5, the substrate 5 is rotated by the rotation mechanism.

### (Pressure Reducing Step (S2))

Subsequently, by opening the open/close valve 47 and by activating the vacuum pump 41, while closing the open/close valves 14a and 14b, the inside of the processing chamber 1 is exhausted. Note that during executing the pressure reducing step (S2), by opening the open/close valve 16b, the inside of a gas reservoir 15b is also exhausted. Then, by adjusting an opening degree of the open/close valve 47, the pressure inside of the processing chamber 1 is controlled to be a prescribed pressure.

### (Temperature Increasing Step (S3))

Subsequently, by supplying power to the resistance heating heater 10, the temperature in the processing chamber 1 is increased to a prescribed temperature. At this time, power supply to the resistance heating heater 10 is controlled, so that a surface temperature of the substrate 5 is set to be, for example, 300 to 600° C.

Note that when the substrate loading step (S1), the pressure reducing step (S2), and the temperature increasing step (S3) are executed, it is preferable to allow the inert gas such as Ar, He, and N₂ to always flow into the processing chamber 1. Thus, it is possible to decrease oxygen concentration in the processing chamber 1 and suppress adhesion of particles (foreign matters) and metal contaminants to the substrate 5.

### (First Processing Gas Supplying Step (S4))

Subsequently, by closing the open/close valve 16b and opening the open/close valve 14a, difference in speed of gas molecules is alleviated, by supplying NH₃ (ammonia) gas, being the first processing gas, into the buffer space 2a. When the pressure in the buffer space 2a reaches a prescribed ignition pressure, high frequency power is supplied from the external power source 20a to a pair of electrodes 17a via the impedance matching apparatus 19a, to generate (ignite) plasma in the buffer space 2a. Then, by the generated plasma, the NH₃ gas supplied into the buffer space 2a is excited (activated) and active particles (radicals) are supplied into the processing chamber 1 via the opening parts 9a. As a result, the NH₃ gas excited (activated) by plasma is chemically adsorbed on the substrate 5.

After elapse of a prescribed time, the power supply to the electrode 27 is stopped and the open/close valve 14a is closed, thus stopping the supply of the NH₃ gas into the processing chamber 1. Then, the NH₃ gas remained in the processing chamber 1 is exhausted by the exhaust line 43, with the open/close valve 47 opened. At this time, by supplying the inert gas such as N₂ into the processing chamber 1, preferably, the NH₃ gas remained in the processing chamber 1 is efficiently exhausted. Thereafter, when the pressure in the processing chamber 1 is reduced to a prescribed pressure, the open/close valve 47 is closed and the inside of the processing chamber 1 is maintained in a state in which the pressure is reduced.

### (Second Processing Gas Filling Step (S4′))

When the first processing gas filling step (S4) and the second processing gas filling step (S4′) are completed, by opening the open/close valve 16b while closing the open/close valves 14a, 14b, 47, the DCS gas in the gas reservoir 15b is introduced into the processing chamber 1 within a prescribed time period (in a very short time), by utilizing the difference in pressure of inside of the gas reservoir 15b and the inside of the processing chamber 1. As a result, the pressure in the processing chamber 1 increases to about 931 Pa, for example, and the surface of the substrate 5 is exposed to a high pressure DCS gas. Then, speedy reaction occurs between the active particles of the NH₃ gas adsorbed on the surface of the substrate 5 and the DCS gas, and a thin film of SiN is formed on the surface of the substrate 5.

After elapse of a prescribed time, by closing the open/close valve 16b and opening the open/close valve 47, the DCS gas and reaction products remained in the processing chamber 1 are exhausted by the exhaust line 43. At this time, by supplying the inert gas such as N₂ into the processing chamber 1, preferably the DCS gas remained in the processing chamber 1 is efficiently exhausted. Thereafter, the pressure in the processing chamber 1 is reduced to a prescribed pressure. Note that after the open/close valve 16b is closed, completion of exhaust of the inside of the processing chamber 1 is not awaited, and the open/close valve 14b is opened to start executing the raw material gas filling step (S4′).

### (Repetition Step (S6))

As described above, after the first processing gas supplying step (S4) and the second processing gas supplying step (S4′) are executed, the step of executing the second processing gas introducing step (S5) is set as one cycle, and cycle processing (repetition processing) in which this cycle is repeated multiple number of times is executed. Thus, the SiN film of a prescribed film thickness can be formed on the substrate 5.

### (Substrate Unloading Step (S7))

After the thin film of a desired film thickness is formed on each substrate 5, the rotation of the substrate 5 by means of the rotation mechanism is stopped. Then, by a reverse procedure to the aforementioned procedure from the substrate loading step (S1) to the pressure adjusting step (S3), the substrate 5 having the thin film of a desired film thickness formed thereon is unloaded from the inside of the processing chamber 1. As described above, the substrate processing step according to this embodiment is completed.

### (5) EFFECT ACCORDING TO THIS EMBODIMENT

According to this embodiment, the upper wall 21a and the lower wall 22a opposed to each other across each opening part 9a are respectively provided on the upper and lower sides of each opening part 9a of the first gas supply part 4a. Then, interval between the upper wall 21a and the lower wall 22a opposed to each other across the opening part 9a, is made gradually larger toward the supply direction of the processing gas. Therefore, the interference of the first processing gas around the opening part 9a is suppressed, and generation of swirl is suppressed and a local pressure decrease is suppressed, thus making it possible to suppress the flow of the first processing gas to the place around the substrate 5 without passing through the place between substrates 5. In addition, the exhaust port 8 is provided in a lower part of the processing chamber 1, and the first processing gas supplied (ejected) from the opening part 9a tends to be dragged to the lower part of the processing chamber 1. However, according to this embodiment, by providing the upper wall 21a and the lower wall 22a on the upper and lower sides of each opening part 9a, the flow of the first processing gas guided to the lower part of the processing chamber 1 is inhibited, and the first processing gas can be guided in a horizontal direction. As described above, the processing speed with respect to the substrate 5 can be increased, and the productivity of substrate processing can be improved. Note that regarding the second processing gas also, the aforementioned effect can be obtained, by the upper wall 21b and the lower wall 22b opposed to each other across each opening part 9b.

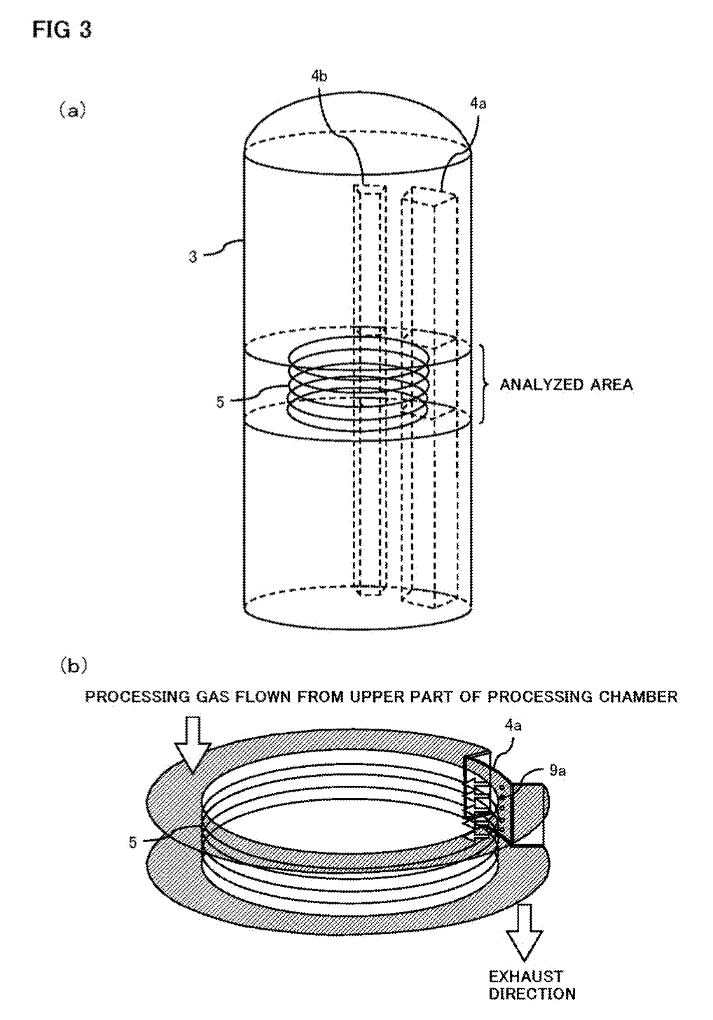

A simulation result of a gas flow velocity distribution and a pressure distribution in thermal processing furnace 20 are shown hereafter. FIG. 3 shows an analyzed area of the gas flow velocity distribution in the thermal processing furnace 20, FIG. 3A shows a position of the analyzed area in the thermal processing furnace, and FIG. 3B shows a partial expanded view of the analyzed area, respectively. In analysis, in order to increase a calculation speed, the thermal processing furnace 20, with its middle part sliced into a ring, is set as the analyzed area, and the second gas supply part 4b is considered to be nonexistent. Five opening parts 9a are provided in the first gas supply part 4a in the analyzed area, and a pitch of this array is set at 13.5 mm. Also, the stacking pitch of the substrates 5 is set at 15.27 mm. In addition, a height position of each opening part 9a is set as a middle position of the substrate 5 and the adjacent substrate 5. Further, not only the processing gas supplied (ejected) from the opening part 9a of the first gas supply part 4a in the horizontal direction, but also the processing gas flown into the analyzed area from the upper part of the thermal processing furnace 20 is added to the object of analysis. The flow rate of the processing gas supplied (ejected) from each opening part 9a in the horizontal direction is set at 29.84, 29.91, 29.98, 30.05, and 30.14 m/sec sequentially from the upper side of the processing chamber 1. In addition, the flow rate of the processing gas flown into the analyzed area from the upper part of the thermal processing furnace 20 is set at 0.84 slm. Note that the temperature of the inner wall of the processing chamber 1 is set at 723K, and the pressure in the processing chamber is set at 133 Pa (1 torr). The kind of the processing gas is ammonia (NH₃) gas.

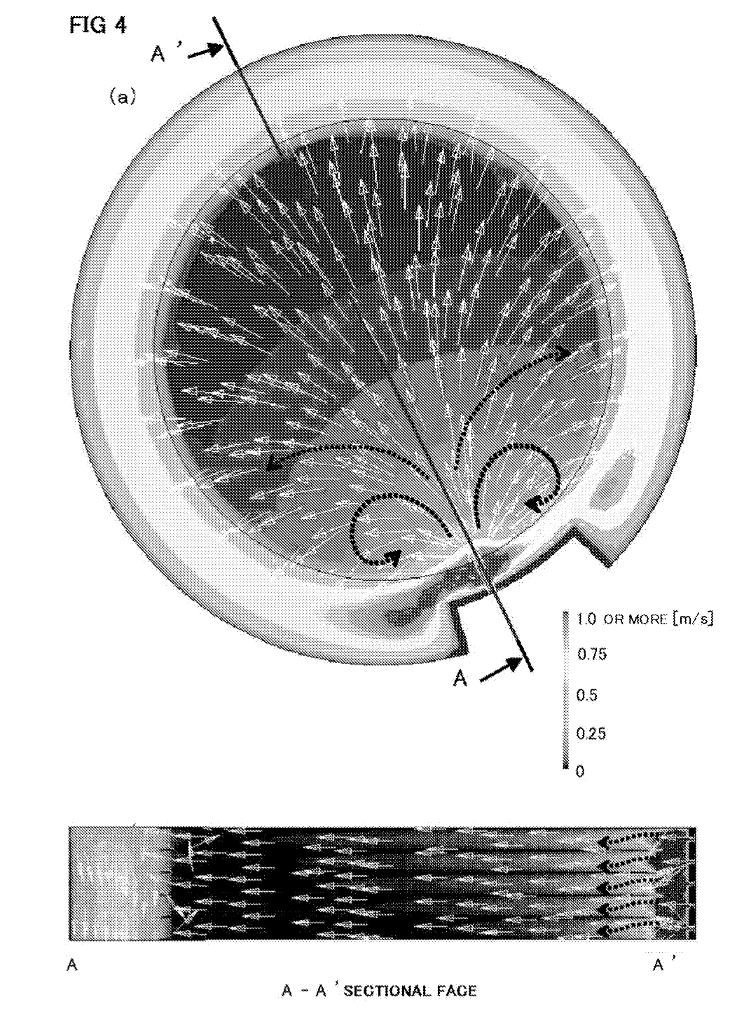

First, FIG. 4 shows an analysis result of the gas flow distribution in a conventional thermal processing furnace 20 not provided with a wall around the opening part 9a of the first gas supply part 4a. FIG. 4A shows an upper surface view of the analyzed area, and FIG. 4B shows a sectional view taken along the line AA′ of FIG. 4A, respectively. In FIGS. 4A and 4B, the flow of the processing gas is shown by broken lines respectively. In FIG. 4, it is found that the processing gas supplied (ejected) into the processing chamber 1 from the opening part 9a of the first gas supply part 4a increases its flow rate around the opening part 9a and decreases its flow rate rapidly on the substrate 5. This clarifies that the processing gas flows to the place around the substrate 5 without passing through the place between substrates 5. In addition, it is found that the exhaust port 8 is provided in the lower part of the processing chamber 1, and the gas supplied (ejected) from the opening part 9a is guided to the lower part of the processing chamber 1.

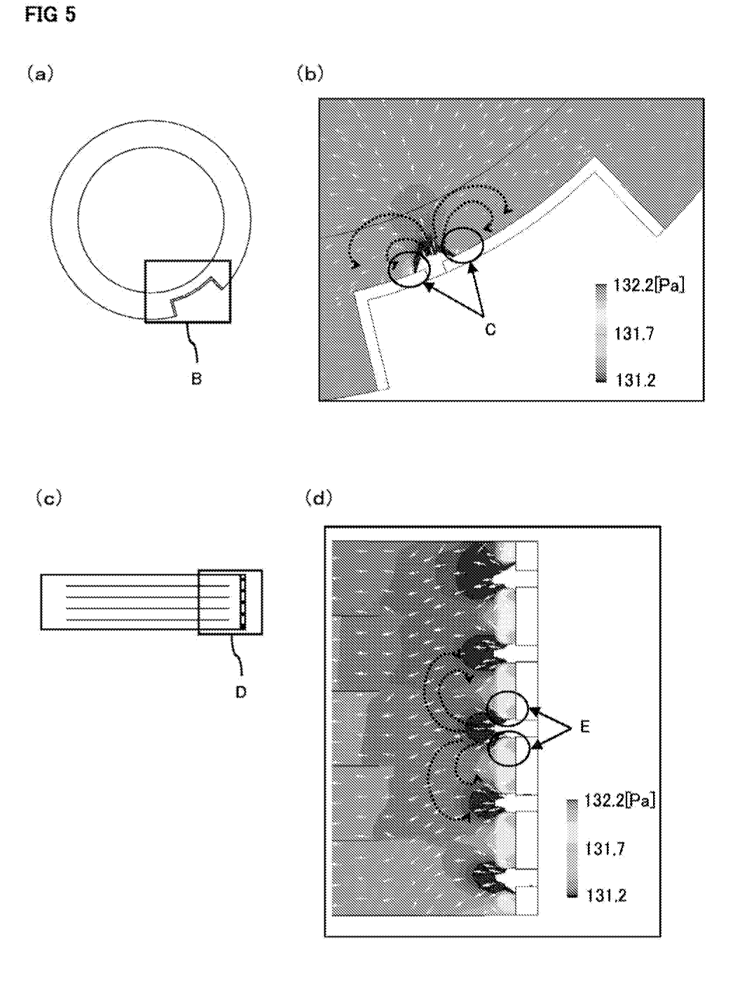

In addition, FIG. 5 shows the analysis result of the pressure distribution in the conventional thermal processing furnace 20 not provided with the wall around the opening part 9a of the first gas supply part 4a. FIG. 5A shows the upper surface view of the analyzed area, FIG. 5B shows the analysis result in an area B of FIG. 5A, FIG. 5C shows a vertical sectional view of the analyzed area, and FIG. 5D shows the analysis result in an area D of FIG. 5C, respectively. In FIGS. 5B and 5D also, the flow of the processing gas is shown by broken lines respectively. In FIG. 5, it is found that the pressure is decreased around the opening part 9a (area C of FIG. 5B, and area E of FIG. 5D), and the processing gas is in a state of swirl. It appears that this swirl is a factor of causing the processing gas to flow to the place around the substrate 5.

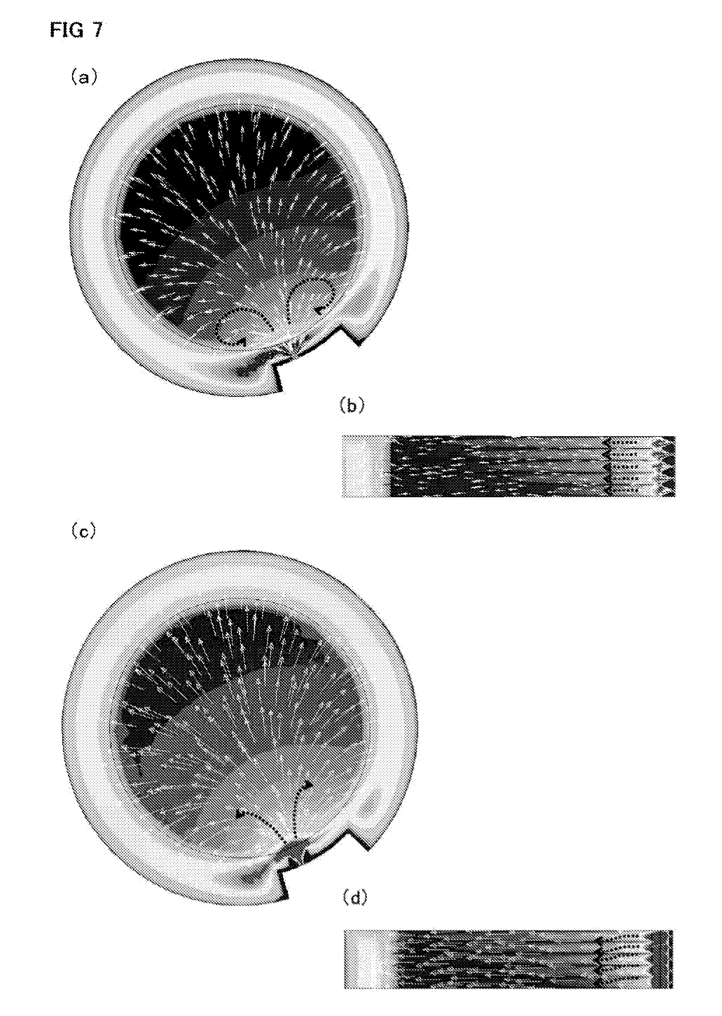

Subsequently, FIG. 7A and FIG. 7B show the analysis result of the gas flow distribution in the thermal processing furnace 20 according to this embodiment. FIG. 7A shows the upper surface view of the analyzed area when the walls are provided on the upper and lower sides of the opening part, and FIG. 7B shows the sectional view taken along the line AA′ of FIG. 7A. In FIG. 7 also, the flow of the processing gas is shown by broken lines respectively. According to these analysis results, the flow rate of the gas on each substrate 5 becomes relatively faster, and it is found that a large amount of processing gas can be supplied to each substrate 5.

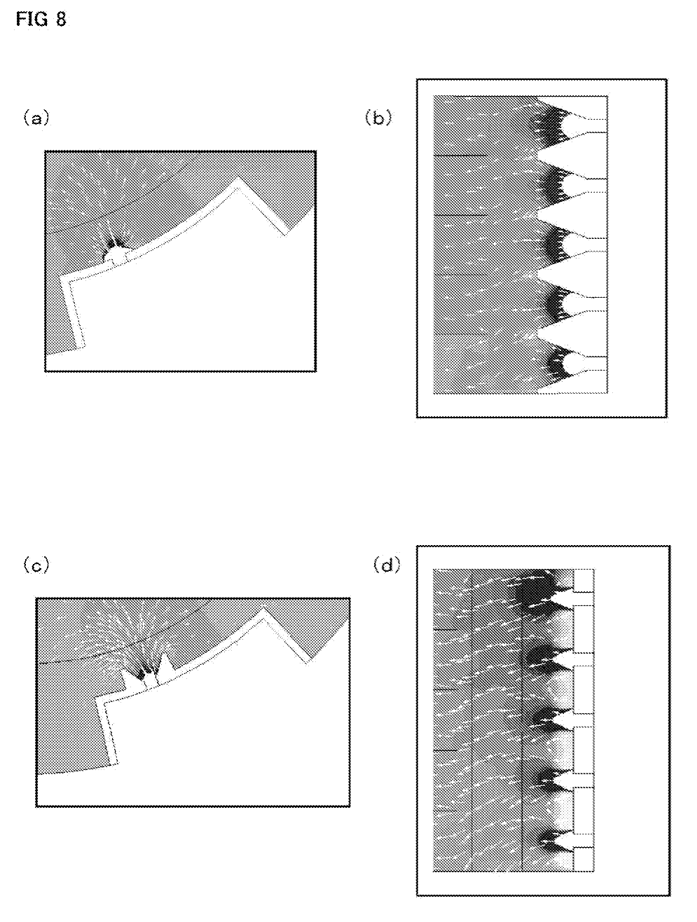

In addition, FIGS. 8A and 8B show the analysis result of the pressure distribution in the thermal processing furnace 20 according to this embodiment. FIG. 8A shows the pressure distribution of the upper surface of the opening part when the walls are provided on the upper and lower sides of the opening part, and FIG. 8B shows the vertical sectional view of FIG. 8A, respectively. According to these analysis results, it is found that in the area where the upper wall 21a and the lower wall 22a are provided, the generation of the swirl of the processing gas can be suppressed, and the decrease of the local pressure can also be suppressed. Note that as shown in FIG. 8B, it is found that suppression effect is particularly remarkable on the upper and lower sides of the opening part 9a provided with the walls.

### Other Embodiments of the Present Invention

Other embodiments of the present invention will be explained hereafter.

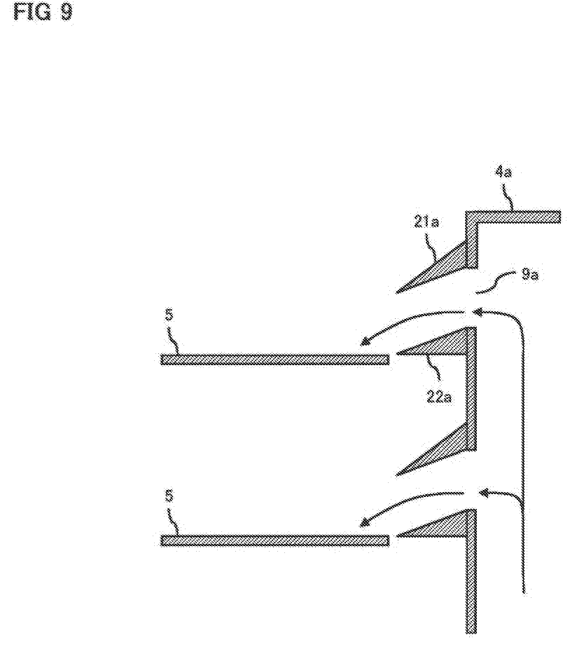

(1) In FIG. 6A, height of a protrusion of the upper wall 21a and the lower wall 22a from the side wall surface of the first gas supply part 4a is set at approximately 10 mm. However, the present invention is not limited thereto, and the height can be suitably adjusted according to the kind of the processing gas and an outer diameter of the substrate 5. In addition, the upper wall 21a and the lower wall 22a opposed to each other across the opening part 9a, have approximately the same sectional shapes. However, the present invention is not limited thereto. Namely, the upper wall 21a and the lower wall 22a opposed to each other across the opening part 9a, are not necessarily required to have the same sectional shapes, and may be different from each other. In addition, an opening angle formed by the upper wall 21a and the lower wall 22a opposed to each other across the opening part 9a, can be set to be different angles according to the kind of the processing gas. For example, when the NH₃ gas and the DCS gas are used as the processing gas, it is preferable to set the aforementioned opening angle at 60±5°. Thus, by suitably setting the shape of the wall provided to the place around the opening parts 9a and 9b so as to correspond to the outer diameter of the substrate 5, further large amount of processing gas can be supplied to each substrate 5.
(2) In the aforementioned embodiments, the processing gas is supplied horizontally to the surfaces of the substrates 5, from the opening parts 9a and 9b provided with walls around them. However, the present invention is not limited thereto, and the walls may be formed as shown in FIG. 9. Namely, each opening part 9a of the first gas supply part 4a is opened respectively between stacked substrates 5, and shapes of the upper wall 21a and the lower wall 22b opposed to each other across the opening part 9a, may be formed so as to supply the processing gas supplied from the opening part 9a toward an obliquely lower direction. In addition, similarly, each opening part 9b of the second gas supply part 4b is opened respectively between the stacked substrates 5, and the upper wall 21b and the lower wall 22b opposed to each other across the opening part 9a, may be formed so as to supply the processing gas supplied from the opening part 9b toward the obliquely lower direction. Thus, by supplying the processing gas toward the obliquely lower direction, namely, by supplying the processing gas toward the surface of the substrate 5, a large amount of processing gas can be supplied to each substrate 5.
(3) In the aforementioned embodiments, the walls are respectively provided on the upper/lower sides of each opening part 9a, 9b. However, the present invention is not limited to the aforementioned embodiments, and for example, the walls may be formed as shown in FIG. 6B. Namely, a left wall 23a and a right wall 24a opposed to each other across the opening part 9a, may be respectively provided on both sides of each opening part 9a of the first gas supply parts 4a and 4b (namely, on the right and left sides of the opening part 9b in the horizontal direction), and an interval between the left wall 23a and the right wall 24a opposed to each other across the opening part 9a, may be made gradually larger toward the supply direction of the processing gas. In addition, similarly, a left wall 23b and a right wall 24b opposed to each other across the opening part 9b, may be respectively provided on both sides of each opening part 9b of the second gas supply part 4b, and the interval between the left wall 23b and the right wall 24b opposed to each other across the opening part 9b, may be made gradually larger toward the supply direction of the processing gas. Further, the opening angle formed by the left wall 23a and the right wall 24a opposed to each other across the opening part 9a, and the opening angle formed by the left wall 23b and the right wall 24b opposed to each other across the opening part 9b, may be set to be different from each other according to the kind of the processing gas. For example, when the NH₃ gas and the DCS gas are used as the processing gas, it is preferable to set the aforementioned opening angle at 60±5°. Thus, by suitably setting the shapes of the walls provided to the place around the opening parts 9a and 9b so as to correspond to the characteristics (viscosity and diffusion coefficient) of the processing gas and the outer diameter of the substrate, further larger amount of processing gas can be supplied to each substrate 5.

FIG. 7C and FIG. 7D show the analysis result of the gas flow distribution in the thermal processing furnace 20 according to this embodiment. FIG. 7C shows the upper surface view of the analyzed area when the walls are provided on both sides of the opening part, and FIG. 7D shows the sectional view of FIG. 7C taken along the line AA′, respectively. According to these analysis results, the flow rate of the gas on each substrate 5 becomes relatively faster, and it is found that further larger amount of processing gas can be supplied to each substrate 5.

In addition, FIG. 8C and FIG. 8D show the analysis result of the pressure distribution in the thermal processing furnace 20 according to this embodiment. FIG. 8C shows the pressure distribution on the upper surface of the opening part when the walls are provided on both sides of the opening part, and FIG. 8D shows the vertical sectional view of FIG. 8A, respectively. According to FIG. 8, it is found that the generation of the swirl of the processing gas can be suppressed and also the decrease of the local pressure can be suppressed, in an area where the upper wall 21a and the lower wall 22a are provided. Note that as shown in FIG. 8C, it is found that the effect on both sides of the opening part 9a provided with the walls is particularly remarkable.

Note that in FIG. 6B, the width between the opposed surfaces of the left wall 23a and the right wall 24a, and a maximum width between the left wall 23a and the right wall 24a in the peripheral direction of the substrate 5 are respectively set at about 10 mm. However, the present invention is not limited thereto, and the widths can be suitably adjusted according to the kind of the processing gas and the outer diameter of the substrate 5. Also, the opening angle formed by the left wall 23a and the right wall 24a across the opening part 9a, can be set so as to be different from each other according to the kind of the processing gas. In addition, the shape and the opening angle formed by the left wall 23b and the right wall 24b can also be suitably set. Thus, by suitably forming the shape of the wall around the opening parts 9a and 9b so as to correspond to the characteristics, etc, of the processing gas, further larger amount of processing gas can be supplied to each substrate 5.

(4) In the aforementioned embodiment, the walls are provided only on the upper/lower sides or both sides of each opening part 9a, 9b. However, the present invention is not limited thereto. Namely, the walls surrounding the outer periphery of the opening parts 9a and 9b may be respectively provided around each opening part 9a, 9b of the first gas supply parts 4a and 4b, and an inner diameter of the walls surrounding the outer periphery of the opening parts 9a and 9b may be made gradually larger toward the supply direction of the processing gas. Specifically, the outer periphery of the opening parts 9a and 9b may be surrounded by four walls, and the outer periphery of the opening parts 9a and 9b may be surrounded by horn-shaped (nozzle-shaped) walls. As described above, when the walls are provided on the upper/lower sides of the opening part, suppression effect of the swirl on the upper/lower sides of the opening part 9a is particularly remarkable. In addition, when the walls are provided on both sides of the opening part 9a, suppression effect of the swirl on both sides of the opening part 9a is particularly remarkable. Namely, by providing the walls surrounding the outer periphery of the opening parts 9a and 9b, it is possible to prevent the gas ejected from the opening parts 9a and 9b, from escaping in a direction not provided with the walls, thus making it possible to supply further larger amount of processing gas to each substrate 5.

In this embodiment also, the walls (upper wall 21a, lower wall 22a, left wall 23a, and right wall 24a) opposed to each other across the opening part 9a, are not necessarily required to have the same sectional shapes, and may be different from one another. In addition, the opening angle formed by the upper wall 21a and the lower wall 22a and the opening angle formed by the left wall 23a and the right wall 24a opposed to each other across the opening part 9a, can be set so as to be different from one another according to the kind of the processing gas. For example, when the NH₃ gas and the DCS gas are used as the processing gas, it is preferable to set the aforementioned opening angle at about 60°. Thus, by suitably forming the shape of the walls around the opening parts 9a and 9b so as to correspond to the characteristics of the processing gas, further larger amount of processing gas can be supplied to each substrate 5.

In addition, in this embodiment also, each opening part 9a of the first gas supply part 4a is opened between the stacked substrates 5, and the upper wall 21a and the lower wall 22b opposed to each other across the opening part 9a, may have the shape capable of supplying the processing gas supplied from the opening part 9a toward the obliquely lower direction. Moreover, similarly, each opening part 9b of the second gas supply part 4b is respectively opened between the stacked substrates 5, and the upper wall 21b and the lower wall 22b opposed to each other across the opening part 9b, may have the shape capable of supplying the processing gas supplied from the opening part 9b toward the obliquely lower direction. Thus, by supplying the processing gas toward the obliquely lower direction, namely, by supplying the processing gas toward the surface of the substrate 5, further larger amount of processing gas can be supplied to each substrate 5.

(5) In the aforementioned, the walls are provided around each opening part 9a, 9b. However, the present invention is not limited thereto. Namely, the opening parts 9a and 9b are provided so as to penetrate the walls of the first gas supply parts 4a and 4b, and the inner diameter of the opening parts 9a and 9b may be made gradually larger toward supply direction of the processing gas. For example, the opening parts 9a and 9b may be formed in a horn-shaped (nozzle-shaped) structure. In such a case also, the same advantage as that of the aforementioned embodiment (4) can be obtained. In addition, the walls are not required to be provided around each opening part 9a, 9b, thus making it possible to reduce the manufacturing cost of the substrate processing apparatus.
(6) In the above description, explanation is given for the embodiment of providing the walls on the upper/lower sides of each opening part 9a, 9b, the embodiment of providing the walls on both sides of each opening part 9a, 9b, the opening of providing the walls for surrounding the outer periphery of each opening part 9a, 9b, and the embodiment of forming each opening part 9a, 9b in the horn-shaped (nozzle-shaped) structure. However, according to the present invention, different kinds of walls may be provided to each of the opening parts 9a and 9b, or the walls may be provided to only either one of the opening parts 9a and 9b, or the walls may be provided only to a part of the opening part out of plural opening parts 9a and 9b.
(7) In the above-described embodiments, explanation is given for a case of depositing SiN on the substrate 5, by using, for example, the DCS gas and the NH₃ gas as the processing gas. However, the kind of the processing gas and the kind of the thin film to be deposited are not limited to the aforementioned embodiments. Moreover, the processing gas is not limited to two kinds, and may be one kind, or three kind or more. Also, explanation is given for a case of activating the processing gas by plasma. However, the present invention can be suitably applied to a case in which activation by plasma is not performed. Namely, the present invention can be suitably applied to a CVD apparatus, an oxide film forming apparatus, a diffusing apparatus, annealing apparatus, and a batch-type plasma apparatus, provided that these apparatuses are substrate processing apparatuses that introduce the processing gas into a reaction vessel and process the substrate.
(8) As described above, the embodiments of the present invention are explained. However, the present invention is not limited to the aforementioned embodiments, and can be suitably modified in a range obvious to the person skilled in the art.

### Other Embodiments of the Present Invention

Other embodiments of the present invention will be additionally described hereunder.

A first aspect of the present invention provides a substrate processing apparatus, including:

a processing chamber that stores stacked substrates;

a gas supply part provided in the processing chamber along a stacking direction of the substrates, having a plurality of opening parts, for supplying desired processing gas horizontally from the opening parts to the surfaces of the substrates;

an exhaust port that exhausts an atmosphere in the processing chamber,

having an upper wall and a lower wall opposed to each other across the opening part, provided respectively on the upper/lower sides of each opening part of the gas supply part, with an interval between the upper wall and the lower wall opposed to each other across the opening part, set to be gradually larger toward a supply direction of the processing gas.

Preferably, according to the first aspect, the upper wall and the lower wall opposed to each other across the opening part, have sectional shapes different from each other.

Preferably, according to the first aspect, an opening angle formed by the upper wall and the lower wall opposed to each other across the opening part is set at about 60°.

Preferably, according to the first aspect, the opening angle formed by the upper wall and the lower wall opposed to each other across the opening part, is set so as to be different respectively according to the kind of the processing gas.

Preferably, according to the first aspect, each opening part of the gas supply part is opened respectively between stacked substrates, and the upper wall and the lower wall opposed to each other across the opening part, have shapes capable of supplying the processing gas supplied from the opening part, toward the obliquely lower direction.

A second aspect of the present invention provides the substrate processing apparatus, including:

the processing chamber that stores the stacked substrates;

the gas supply part provided in the processing chamber along the stacking direction of the substrates, having a plurality of opening parts, for supplying desired processing gas horizontally from the opening parts to the surfaces of the substrates; and

the exhaust port that exhausts the atmosphere in the processing chamber,

having a left wall and a right wall opposed to each other across the opening part provided on both sides of each opening part of the gas supply part, with an interval between the left wall and the right wall opposed to each other across the opening part, set to be gradually larger toward the supply direction of the processing gas.

Preferably, according to the second embodiment, the opening angle formed by the left wall and the right wall opposed to each other across the opening part, is set to be about 60°.

A third aspect of the present invention provides the substrate processing apparatus, including:

the processing chamber that stores the stacked substrates;

the gas supply part provided in the processing chamber along the stacking direction of the substrates, having a plurality of opening parts, for supplying desired processing gas horizontally from the opening parts to the surfaces of the substrates; and

the exhaust port that exhausts the atmosphere in the processing chamber,

having walls that surround outer periphery of the opening parts provided around each opening part of the gas supply part, with the inner diameter of the walls surrounding the outer periphery of the opening parts being set to be gradually larger toward the supply direction of the processing gas.

Preferably, according to the third aspect, at least either one of the opening angle formed by the upper wall and the lower wall across the opening part, and the opening angle formed by the left wall and the right wall opposed to each other across the opening part, is set to be about 60°.

Preferably, according to the third aspect, each opening part of the gas supply part is opened between the stacked substrates, and the upper wall and the lower wall opposed to each other across the opening part are respectively set so as to supply the processing gas supplied from the opening part, toward the obliquely lower direction.

A fourth aspect of the present invention provides the substrate processing apparatus, including:

the processing chamber that stores the stacked substrates;

the gas supply part provided in the processing chamber along the stacking direction of the substrates, having a plurality of opening parts, for supplying desired processing gas horizontally from the opening parts to the surfaces of the substrates; and

the exhaust port that exhausts the atmosphere in the processing chamber,

having the opening parts provided so as to penetrate the wall of the gas supply part,

with an inner diameter of the opening parts set to be gradually larger toward the supply direction of the processing gas.

What is claimed is:

1. A substrate processing apparatus, comprising:
a processing chamber that stores stacked substrates;
a gas supply part provided in said processing chamber along a stacking direction of said substrates, having a plurality of opening parts, for supplying desired processing gas horizontally from said opening parts to the surfaces of said substrates;
an exhaust port that exhausts an atmosphere in said processing chamber,
having an upper wall and a lower wall opposed to each other across said opening part, provided respectively on the upper/lower sides of each opening part of said gas supply part, with an interval between said upper wall and said lower wall opposed to each other across the opening part, set to be gradually larger toward a supply direction of said processing gas.

2. The substrate processing apparatus according to claim 1, wherein said upper wall and said lower wall opposed to each other across said opening part have mutually different sectional shapes.

3. The substrate processing apparatus according to claim 1, wherein an opening angle formed by said upper wall and said lower wall opposed to each other across said opening part is set to be approximately 60°.

4. The substrate processing apparatus according to claim 1, wherein an opening angle formed by said upper wall and said lower wall opposed to each other across said opening part is set to be 60±5°.

5. The substrate processing apparatus according to claim 1, wherein each opening part of said gas supply part is opened respectively between stacked substrates, and shapes of said upper wall and said lower wall opposed to each other across said opening part are set so as to supply the processing gas supplied from said opening part toward obliquely lower direction.

6. The substrate processing apparatus according to claim 1, wherein an opening angle formed by said upper wall and said lower wall opposed to each other across said opening part is different respectively, according to the kind of the processing gas.

7. A substrate processing apparatus, comprising:
a processing chamber that stores stacked substrates;
a gas supply part provided in said processing chamber along a stacking direction of said substrates, having a plurality of opening parts, for supplying desired processing gas horizontally from said opening parts to the surfaces of said substrates;
an exhaust port that exhausts an atmosphere in said processing chamber,
having a left wall and a right wall opposed to each other across said opening part, provided respectively on the both sides of each opening part of said gas supply part, with an interval between said left wall and said right wall opposed to each other across the opening part, set to be gradually larger toward a supply direction of said processing gas.

8. The substrate processing apparatus according to claim 7, wherein an opening angle formed by said left wall and said right wall opposed to each other across said opening part is set to be approximately 60°.

9. The substrate processing apparatus according to claim 7, wherein an opening angle formed by said left wall and said right wall opposed to each other across said opening part is set to be 60±5°.

10. A substrate processing apparatus, comprising:
a processing chamber that stores stacked substrates;
a gas supply part provided in said processing chamber along a stacking direction of said substrates, having a plurality of opening parts, for supplying desired processing gas horizontally from said opening parts to the surfaces of said substrates;
an exhaust port that exhausts an atmosphere in said processing chamber,
having a wall surrounding an outer periphery of said opening part being provided around each opening part of said gas supply part, and an inner diameter of said wall surrounding the outer periphery of said opening part being set to be gradually larger toward a supply direction of said processing gas.

11. The substrate processing apparatus according to claim 10, wherein at least either one of an opening angle formed by said upper wall and said lower wall opposed to each other across said opening part and an opening angle formed by said left wall and said right wall opposed to each other across this opening part, is set to be approximately 60°.

12. The substrate processing apparatus according to claim 10, wherein at least either one of an opening angle formed by said upper wall and said lower wall opposed to each other across said opening part and an opening angle formed by said left wall and said right wall opposed to each other across this opening part, is set to be 60±5°.

13. The substrate processing apparatus according to claim 10, wherein each opening part of said gas supply part is opened between stacked substrates, and shapes of said upper wall and said lower wall opposed to each other across said opening part are respectively set so as to supply the processing gas supplied from said opening part toward an obliquely lower direction.

14. A substrate processing apparatus, comprising:
a processing chamber that stores stacked substrates;
a gas supply part provided in said processing chamber along a stacking direction of said substrates, having a plurality of opening parts, for supplying desired processing gas horizontally from said opening parts to the surfaces of said substrates;
an exhaust port that exhausts an atmosphere in said processing chamber,
with said opening part being provided so as to penetrate the wall of the gas supply part, and an inner diameter of said opening part being set to be gradually larger toward a supply direction of said processing gas.

15. A substrate processing apparatus, comprising:
a processing chamber that stores stacked substrates;
a first gas supply part provided along a stacking direction of said substrates in said processing chamber, having a plurality of first opening parts, for supplying a first processing gas horizontally to the surfaces of said substrates from said first opening parts;
a second gas supply part provided along the stacking direction of said substrates in said processing chamber, having a plurality of second opening parts, for supplying a second processing gas horizontally to the surfaces of said substrates from said second opening parts; and
an exhaust port that exhausts an atmosphere in said processing chamber,
having a first upper wall and a first lower wall opposed to each other across said first opening parts, provided respectively on upper/lower sides of each of said first opening parts of said first gas supply part, and an interval between said first upper wall and said first lower wall being set to be gradually larger toward a supply direction of said first processing gas.

16. A manufacturing method of a semiconductor device, comprising:
loading substrates for loading stacked substrates into a processing chamber;
setting as one cycle, a first processing gas supplying step for supplying a first processing gas horizontally to surfaces of said substrates, from a plurality of opening parts of a first gas supply part provided in said processing chamber along a stacking direction of said substrates, and a second processing gas supplying step for supplying a second processing gas horizontally to the surfaces of said substrates from a plurality of second opening parts of a second gas supply part provided in said processing chamber along the stacking direction of said substrates, and repeating this cycle multiple number of times; and
unloading substrates for unloading said substrates from said processing chamber,
having a first upper wall and a first lower wall opposed to each other across said first opening parts provided on upper/lower sides of each of said first opening parts, and an interval between said first upper wall and said first lower wall being set to be gradually larger toward a supply direction of said first processing gas, thereby suppressing an interference of said first processing gas around said first opening part, and
having a second upper wall and a second lower wall opposed to each other across said second opening parts provided on the upper/lower sides of each of said second opening parts, and an interval between said second upper wall and said second lower wall being set to be gradually larger toward the supply direction of said second processing gas, thereby suppressing the interference of said second processing gas around said second opening part.

17. A substrate processing apparatus, comprising:
a processing chamber that stores stacked substrates;
a first gas supply part provided in said processing chamber along a stacking direction of said substrates, having a plurality of first opening parts, for supplying a first processing gas horizontally to surfaces of said substrates from said first opening parts;
a second gas supply part provided in said processing chamber along the stacking direction of said substrates, having a plurality of second opening parts, for supplying a second processing gas horizontally to the surfaces of said substrates from said second opening parts; and
an exhaust port that exhausts an atmosphere in said processing chamber,
having a first upper wall and a first lower wall opposed to each other across said first opening parts respectively provided on upper/lower sides of each of said opening parts of said first gas supply part, and an interval between said first upper wall and said first lower wall being set to be gradually larger toward a supply direction of said first processing gas.

18. A manufacturing method of a semiconductor device, comprising:
loading substrates for loading stacked substrates into a processing chamber;
setting as one cycle, a first processing gas supplying step for supplying a first processing gas horizontally to surfaces of said substrates, from a plurality of opening parts of a first gas supply part provided in said processing chamber along a stacking direction of said substrates, and a second processing gas supplying step for supplying a second processing gas horizontally to the surfaces of said substrates from a plurality of second opening parts of a second gas supply part provided in said processing chamber along the stacking direction of said substrates, and repeating this cycle multiple number of times; and
unloading substrates for unloading said substrates from said processing chamber,
having a first upper wall and a first lower wall opposed to each other across said first opening parts provided on upper/lower sides of each of said first opening parts, and an interval between said first upper wall and said first lower wall being set to be gradually larger toward a supply direction of said first processing gas, thereby suppressing an interference of said first processing gas around said first opening part.
